(19) United States
(12) Patent Application Publication
(10) Pub. No.: US 2024/0431210 A1
(43) Pub. Date: Dec. 26, 2024

(54) THERMOELECTROMECHANICAL SYSTEM AND METHOD OF MAKING SAME

(71) Applicant: THE ROYAL INSTITUTION FOR THE ADVANCEMENT OF LEARNING/MCGILL UNIVERSITY, Montréal (CA)

(72) Inventors: Abdolhamid AKBARZADEH, Montréal (CA); Jiahao SHI, Montréal (CA); Agus SASMITO, Montréal (CA); Seyed ARMIN MIRABOLGHASEMI, Montréal (CA); Saad AKHTAR, Montréal (CA); Kang JU, Montréal (CA); Haoyu CHEN, Montréal (CA)

(21) Appl. No.: 18/750,137

(22) Filed: Jun. 21, 2024

Related U.S. Application Data
(60) Provisional application No. 63/509,304, filed on Jun. 21, 2023.

(51) Int. Cl. H10N 30/85; H01M 10/48; H10N 30/045

(52) U.S. Cl. CPC H10N 30/85; H01M 10/48; H10N 30/045

(57) ABSTRACT

The thermoelectromechanical system can have a porous structure having a spinodoid geometry and formed of an electrically polarized ferroelectric material, the structure occupying a volume and having a first area spaced apart from a second area; and a device electrically connected to the first area and to the second area.

### BACKGROUND

Ferroelectric effect generates electrical power from mechanical oscillations and temperature fluctuations. While many devices exist which harness the ferroelectric effect, there remained room for improvement.

### SUMMARY

It was found that tailoring the microarchitectures of ferroelectric materials provides a promising route for enhancing their ferroelectric performance. For instance, an architected cellular structure, spinodoid, is used to construct piezoelectric metamaterials. A numerical homogenization can predict their effective multiphysical properties. A poling simulation can be conducted to determine the poling direction of the local element. The determined poling direction can then be imported to the numerical homogenization model to extract the effective mechanical and piezoelectric constants. The effects of relative density and spinodoid geometrical parameters on ferroelectric figure of merit, a metric for assessing the performance of ferroelectric metamaterials as sensors and energy harvesters, are explored. Digital light processing can be adapted for 3D printing the complex spinodoid piezoelectric metamaterials. In an embodiment, a 3D printed sample shows high precision and maintains the same topological features as the designed spinodoid. Experimental test of piezo/pyroelectric charge constant and dielectric constant also can also yield performance levels of ferroelectric spinodoids allowing their use in applications such as sensors, actuators, and energy harvesters.

In accordance with one aspect, there is provided a thermoelectromechanical system comprising: a porous structure having a spinodoid geometry and formed of an electrically polarized ferroelectric material, the structure occupying a volume and having a first area spaced apart from a second area; and a device electrically connected to the first area and to the second area.

When the thermoelectromechanical system is embodied as a sensor, the device can be a voltmeter for instance.

When the thermoelectromechanical system is embodied as an actuator, the device can be an electrical power source for instance.

When the thermoelectromechanical system is embodied as an energy harvester, the device can be a generator for instance.

In accordance with another aspect, there is provided a method of making a porous structure, the method comprising: mixing ferroelectric powder and resin into a mixture; 3D printing the mixture into a spinodoid geometry, thereby forming the porous structure; debinding the porous structure; sintering the debinded porous structure; and electrically polarizing the sintered porous structure.

In accordance with another aspect, there is provided a porous structure having a spinodoid geometry and formed of an electrically polarized ferroelectric material

Many further features and combinations thereof concerning the present improvements will appear to those skilled in the art following a reading of the instant disclosure.

### DESCRIPTION OF THE FIGURES

In the figures,

FIG. 1 is a view of an example of a thermoelectromechanical system;

FIG. 2A presents a phase separation process of two homogeneous phases through spinodal decomposition, whereas FIG. 2B presents the spherical design space determined by θ1, θ2, and θ3 in our efficient Gaussian random field (GRF) method where the black dots show the randomly sampled wave vectors, where the porous spinodoid is generated by setting level cut value in GRF;

FIG. 3A generally presents fabrication of architected ferroelectric ceramic with DLP printing of low viscous slurry consisting of ferroelectric ceramic powders and photosensitive resin, in which case the powders are first surface treated through dispersants to reduce the viscosity of the printed slurry.

FIGS. 3B and 3C are schematic illustrations of the two-step sintering (b) and electric poling (c) processes of the fabricated green porous structure;

FIG. 3D is an image of the as-fabricated colosseum, where after poling, electrodes are attached to both surfaces of the building floor, and the voltage response is recorded under the impact of a slender rod;

FIG. 3E is a schematic of the contact polarization setup;

FIG. 3F is a simulated polarization electric field;

FIG. 3G shows poled and unpolarized local elements;

FIG. 4A generally presents piezoelectric constant d33 of spinodoid and diamond metamaterials with different relative densities;

FIG. 4B generally presents piezoelectric voltage constant g33 of spinodoid and diamond metamaterials with different relative densities;

FIG. 5A generally presents transverse piezoelectric properties of spinodoid ferroelectric metamaterials where piezoelectric constants d31 and d32 of spinodoid and diamond metamaterials with different relative densities;

FIG. 5B generally presents voltage responses of one columnar and two longitudinal lamellar spinodoids under unidirectional compression along three directions, respectively;

FIG. 5C presents functionally graded (FG) spinodoid metamaterial and its 3D printed sample consisting of lamellar (0°, 30°, 0°, 0.45) and isotropic (45°, 45°, 45°, 0.55) topologies;

FIG. 6A generally presents pyroelectric properties of spinodoid ferroelectric metamaterials with pyroelectric constant p3 and pyroelectric figures of merit; and

FIG. 6B generally presents the FV of spinodoid and diamond ferroelectric metamaterials with different relative densities.

### DETAILED DESCRIPTION

Ferroelectric materials, including polymer polyvinylidene fluoride (PVDF), single crystal lead magnesium niobate-lead titanate (PMN-PT), ceramics such as barium titanate (BaTiO₃), and lead zirconate titanate (PZT), and composites, exhibit a distinctive combination of piezoelectric and pyroelectric properties. The piezoelectric effect transforms mechanical stress or strain into an electrical charge and vice versa, while the pyroelectric effect converts temperature fluctuation into an electrical charge. Due to their multifunctional properties, ferroelectric materials can have applications in sensors, ultrasonic imaging, infrared detectors, actuation, and energy harvesting. Apart from chemical modification, deliberately optimizing the microarchitecture of cellular ferroelectric materials has emerged as a promising approach to enhance their piezoelectric and pyroelectric properties, even with unprecedented values.

Benefiting from their microarchitectures, metamaterials can offer many intriguing properties not found in naturally occurring or chemically synthesized materials; such as negative refractive index, negative effective density, and structural multistability. The introduction of porosity in ferroelectric materials improves figures of merit for different piezoelectric and pyroelectric applications, which is attributed to a remarkable decrease in the dielectric constant. For example, the longitudinal piezoelectric voltage constant g33, evaluating the sensitivity of piezoelectric voltage-type sensors, can be inversely proportional to the dielectric constant. Specifically, employing series-connected porosity can lead to a further reduction in dielectric constant compared to parallel-connected and randomly distributed porosity, thereby enhancing the ferroelectric figures of merit, revealing the potential of rationally designed cellular materials. However, the limited capabilities of conventional processing methods, such as Burnt-out polymer spheres (BURPS), etching and dicing, laser or ultrasonic cutting, and freeze casting, may hinder the exploration of architected ferroelectric metamaterials with complex and precise microstructures. 3D printing of ferroelectric ceramics and composites may open an effective pathway for low-cost fabrication methods, enabling the production of delicate and high-fidelity structural features. By tuning the spatial arrangement, 3D-printed truss-based ferroelectric metamaterials can exhibit desired piezoelectric anisotropy and actuation modes.

Smooth shell-based metamaterials can have potential in achieving high fluid permeability, enhanced heat transfer, and improved stiffness and strength with less sensitivity to stress concentration compared to truss- and plated-based metamaterials. Inspired by spinodal decomposition during the phase separation process, a new type of metamaterials called spinodoid has been constructed utilizing efficient Gaussian random fields (GRFs). Similar to triply periodic minimal surfaces (TPMSs), spinodoid metamaterials comprise of smooth, non-intersecting surfaces, leading to ultrahigh energy absorption and extreme mechanical resilience. The broad design space of spinodoids provides a range of options for geometry anisotropy with diverse resources of structural features, presenting opportunities for spatially variant architectures. In addition, unlike periodic truss-, plate-, and TPMS-based metamaterials, spinodoid microarchitectures are non-periodic and allow for creation of functionally graded designs with smooth transitions between different spinodoid classes. Exploiting spinodoid metamaterials made of ferroelectric materials facilitates the realization of programmable piezoelectric and pyroelectric properties with intriguing multiphysical anisotropy and high figure of merits.

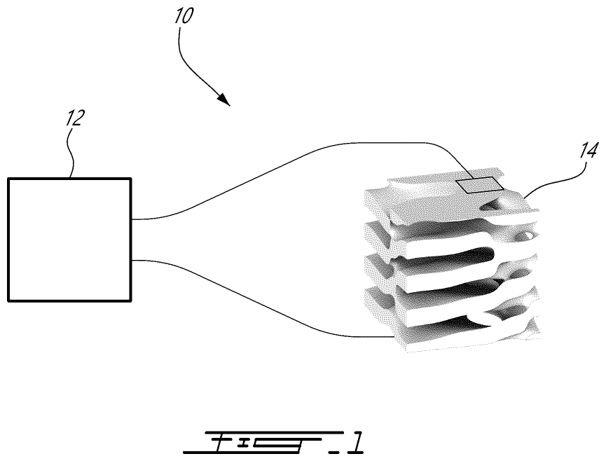

FIG. 1 presents an example of a thermoelectromechanical system 10 harnessing the concepts presented above. More specifically, the thermoelectromechanical system 10 has a porous structure 14 having a spinodoid geometry and can be referred to as a spinodoid for short. The porous structure 14 is made of a polarized ferroelectric material, and as such can be referred to as a polarized ferroelectric spinodoid for short. An electrical and/or electronic device 12, which, in some embodiments, may be a meter such as a voltmeter for instance, is connected to two spaced apart locations of the porous structure 14 via suitable electric conductors such as wires and/or electric contacts, in a manner to form an electric circuit across the polarized ferroelectric spinodoid. The polarized ferroelectric spinodoid can have piezoelectric properties such that when the porous structure 14 is deformed, a change in its electric properties can be sensed by the meter, such as a change in voltage for instance, or conversely, a change in its electric properties may be imparted, such as by imparting a voltage difference via the conductors, in a manner to cause the porous structure 14 to deform and potentially exert a mechanical force. The polarized ferroelectric spinodoid can have pyroelectric properties such that when the temperature of the porous structure 14 changes, a change in its electric properties can be sensed by the meter, such as a change in voltage for instance. The polarized ferroelectric spinodoid can have both pyroelectric and piezoelectric properties. Various applications are possible as will be discussed herein, examples of which include lightweight ferroelectric metamaterials can be employed for structural health monitoring to detect building loading conditions and defects, while delicately designed functional graded ferroelectric spinodoid serves as a one-step multidirectional force sensor, capable of distinguishing the force along three directions. The introduced design framework allows for the realization of advanced multifunctional materials in the form of programmable ferroelectric spinodoid metamaterials for potential applications in accelerometers, pressure sensors, precision positioning, temperature sensors, and smart building bricks.

In the detailed description of multiple example embodiments which follows, structure-property linkage of ferroelectric spinodoid metamaterials across a broad design space is presented. A computational framework that combines numerical homogenization for 3D printed ferroelectric ceramics and deep learning method, i.e., convolutional neural network (CNN), is proposed to accelerate the mapping process between microstructure features and their effective multiphysical properties. Through the analysis of various types of ferroelectric spinodoids predicted by a well-trained CNN, the mechanism behind their wide material selection regions can be revealed, which exhibits high longitudinal piezoelectric properties, diverse transverse piezoelectric anisotropy, and enhanced piezoelectric and pyroelectric figure of merits, supported by the experimental tests of printed samples.

It will first be noted that parametric spinodoid metamaterials can be derived from spinodal topologies, which are a type of stochastic bicontinuous microstructures and can originate from a spinodal decomposition of two homogeneous phases. Spinodal decomposition is a near-instantaneous diffusion-driven phase transformation that converts a single-phase material into a two-phase material (one phase possibly being a void space). The two phases are arranged in a bicontinuous topology and separated by a surface with nearly a uniform negative Gaussian curvature and a nearly zero mean curvature. The homogeneous parent phase grows with time until two separate phases are formed. This phenomenon has been used to produce fine-scale interconnected porous polymer and metal foam with high permeability, high specific electric capacity, extreme mechanical resilience, and enhanced stiffness and strength. A microarchitecture of a porous nickel can be fabricated by coating the cellular spinodal polymer.

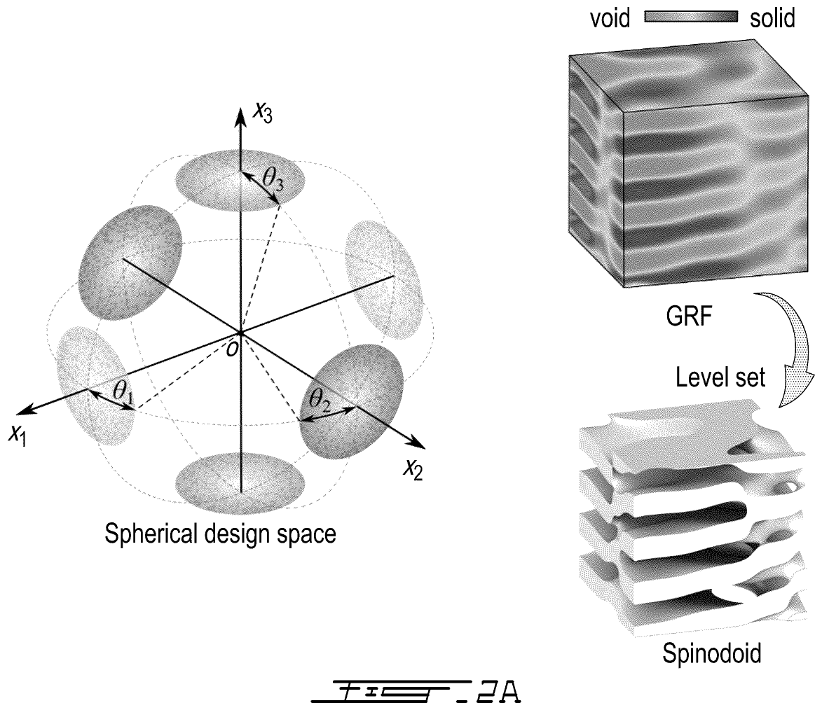

Mathematically, the spinodal decomposition process can be described by a phase field approach using the Cahn-Hilliard equation. However, it can take hours on a modern computer at the time of filing this specification to solve this time-dependent phase separation problem. An alternative method is to use a superposition of a large number (N>>1) of standing sinusoidal waves with a constant wavenumber (β>0) to denote the early stage of spinodal decomposition, represented by a truncated Fourier series or a Gaussian random field (GRF) as follow:

$$φ ( x ) = \sqrt{\frac{2}{N}} {\sum }_{i = 1}^{N} cos ( β {n}_{i} \cdot x + {γ}_{i} ) , {γ}_{i} ∼ [ 0 , 2 π ] \qquad ( 1 )$$

where x is position vector, nᵢ is unit wave vector randomly selected from the marked spherical design space in FIG. 2A, and γᵢ is random phase angle sampled from a uniform distribution within preferred design space. N=1000 different sinusoidal waves are used to calculate GRF and the constant wavenumber β is assumed 12π. From Eq. (1), we can generate a spinodoid by computing level sets of the phase field. Here, a binary indicator function, G(x), is defined to determine the material or void at position x:

$$G ( x ) = \{ \begin{matrix}1 & if φ ( x ) \leq {φ}_{0} ( Solid material ) \\ 0 & if φ ( x ) \leq {φ}_{0} ( Void / air )\end{matrix} \qquad ( 2 )$$

where G(x)=0 indicates void, while 1 means solid material; φ₀ is the level cut value calculated by exploiting the Gaussian properties of the random field as φ₀=\sqrt{2} inverf (2ρ−1), where inverf ( . . . ) is the inverse error function, and ρ is relative density. The whole modelling process is presented in FIG. 2A.

Without restriction, the wave vector, nᵢ, is randomly sampled from the entire spherical surface, thus the generated spinodoids are isotropic. In order to design distinctive spinodoid topologies with anisotropic properties, the wave vector is restricted to specific spherical regions, favoring some directions and neglecting the others. As shown in FIG. 2A, three angles, i.e., θ₁, θ₂, and θ₃<π/2, are used to determine the design space and are related to axis x₁, x₂ and x₃, respectively, in a Cartesian coordinate system. For example, θ₁=θ₂=0° and nonzero θ₃ lead to a pair of red spherical sampling areas in the design space. Therefore the parametric spinodoids can be simply described by four parameters, i.e., θ₁, θ₂, θ₃, and ρ. In order to avoid disjoint solid domains and maintain structural features, the relative densities and angles are restricted to ρ∈[0.3, 0.7], and θᵢ ∈[0°]∪[30°, 90°], respectively. Based on the covered design space, four types of spinodoids are shown in FIG. 2B, i.e., lamellar, columnar, cubic, and isotropic with geometry parameters (θ₁, θ₂, θ₃, ρ) as (0°, 0°, 30°, 0.5), (30°, 30°, 0°, 0.5), (30°, 30°, 30°, 0.5), and (45°, 45°, 45°, 0.5), respectively. An example of a cubic type structure can be trabecular bone-like, and an example of a columnar type structure can be wood-like.

Let us now explore the potential of spinodoids geometries in improving ferroelectric properties of metamaterials. A finite element (FE) homogenization method can be used to obtain the effective piezoelectric (d₃₁, d₃₂, d₃₃, d₄₂, d₅₁), dielectric (k₁₁^{σ}, k₂₂^{σ}, and k₃₃^{σ}), and pyroelectric (p₃^{σ}) constants of the designed ferroelectric spinodoids. However, the infinite combinations of θ₁, θ₂, θ₃, and ρ make it impossible to investigate all spinodoid topologies. An efficient deep learning (DL) network, i.e., 3D conventional neuron network (3D-CNN), can be utilized to establish the structure-property linkage with a limited number of spinodoids. FE homogenization on 6000 spinodoids can be conducted and serve as a ground truth for the training. For a regression problem, a 3D-CNN model usually has a stack of several feature extraction and regression layers. The spinodoid microarchitectures are discretized to 50×50×50 pixels and used as input for the CNN training. The convolutional layer forms the core component of CNN and employs filters to extract the salient features of microstructures. The pooling layers reduce dimensionality while preserving the most essential structural features. The output of multiple stacks of convolutional and pooling layers are then fed into fully connected layers, which are flattened to a vector representing the concerned ferroelectric properties. An excellent agreement was achieved between the predicted and true p₃^{σ} validates the reliability of the well-trained 3D-CNN model, indicated by the coefficient of determination, R², of 0.998, normalized mean absolute error, NMAE, of 0.90%, and normalized mean absolute square error, NMASE, of 1.17%. Considering the rich resource of structural features from different types of spinodoids, we expect the knowledge learned by the 3D-CNN can be transferred to other type of microarchitectures. Transfer learning enables us to retrain the pre-trained model with few cases but achieve excellent performance. After retraining with only 400 D shellulars, the 3D-CNN model can predict the p₃^{σ} of another 1058 unseen shellulars well.

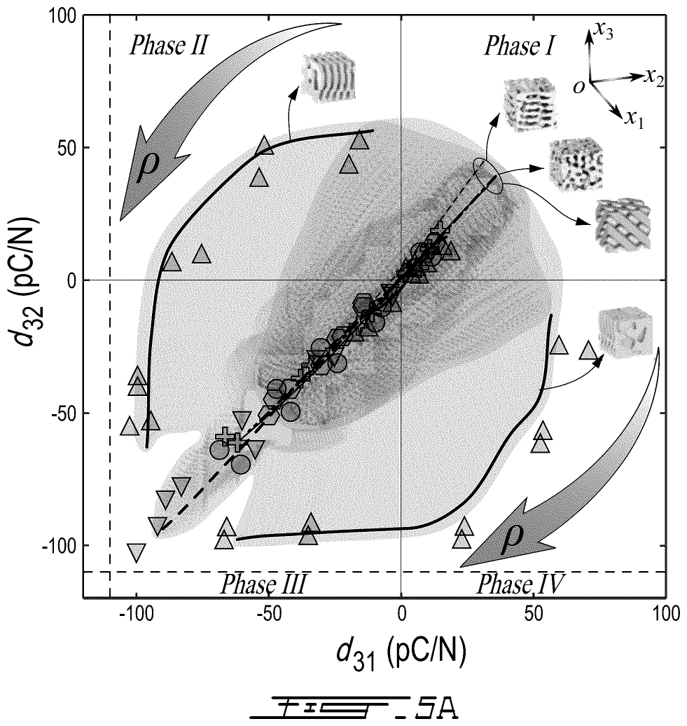

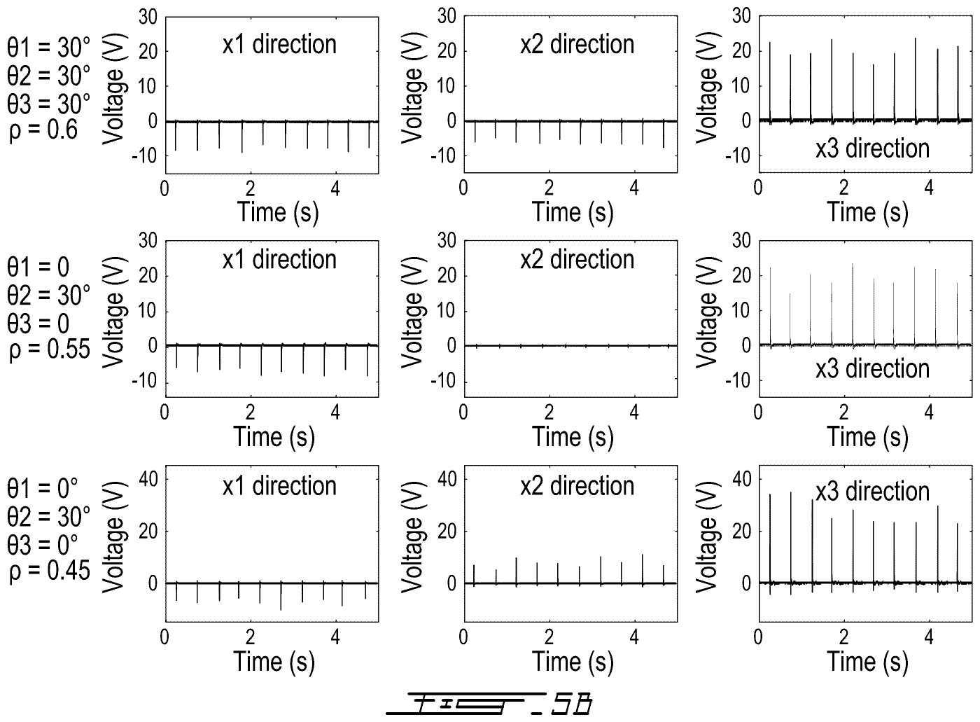

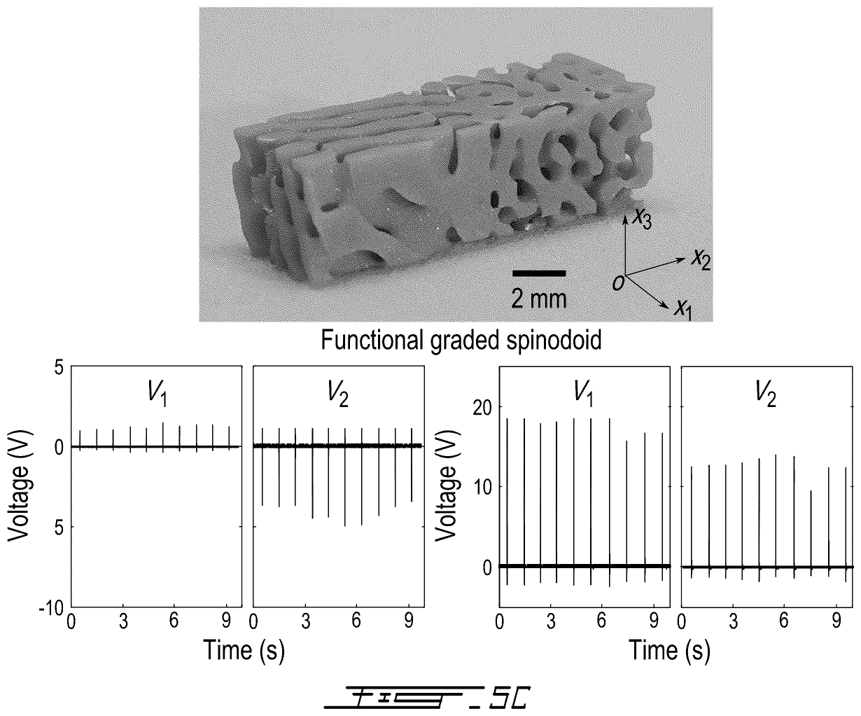

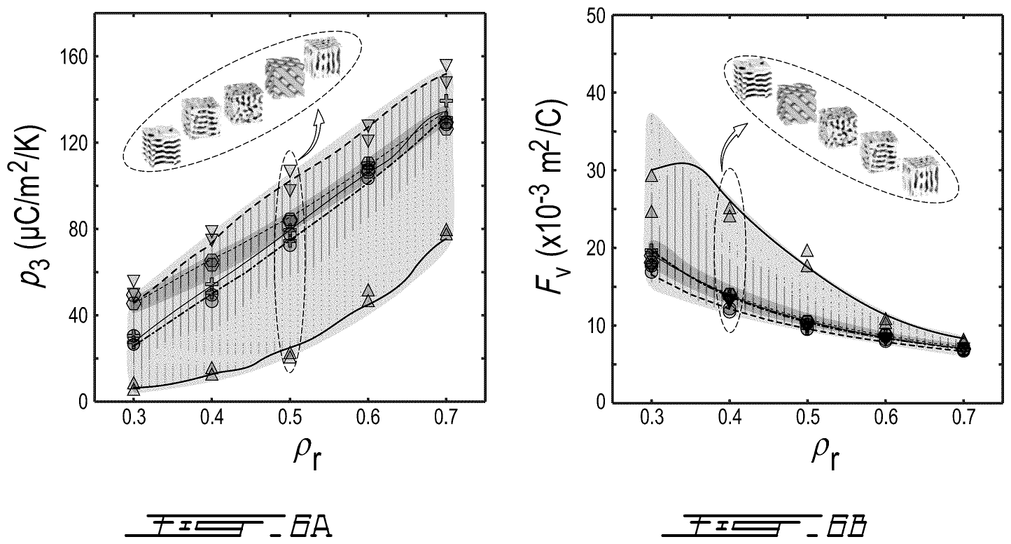

In the following FIGS. 4 and 5, around 2.8 million spinodoid topologies (small blue dots in the blue area) and 24.4 thousand diamond topologies (small red dots in the red area) are predicted by the well-trained CNN.

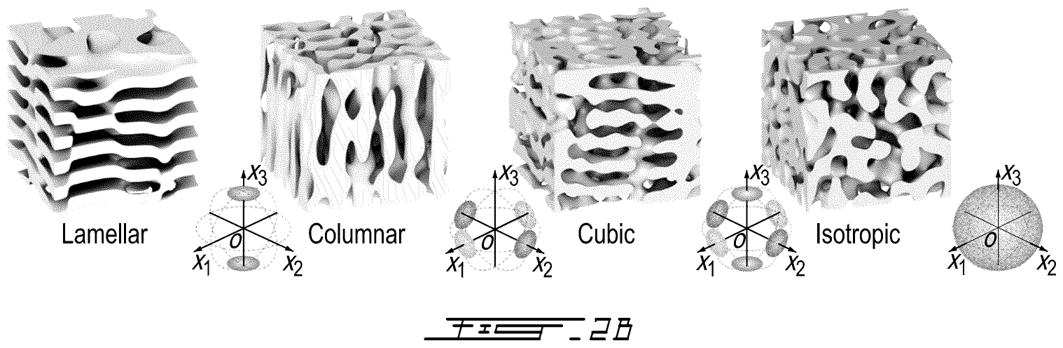

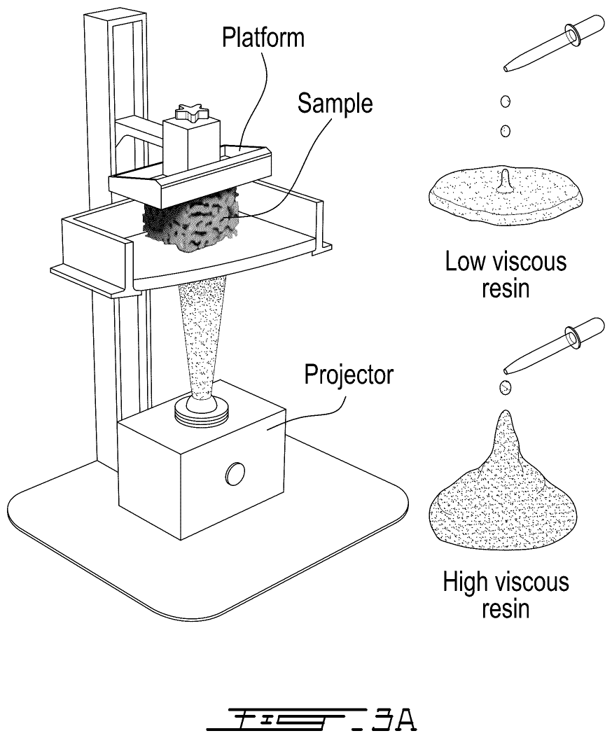

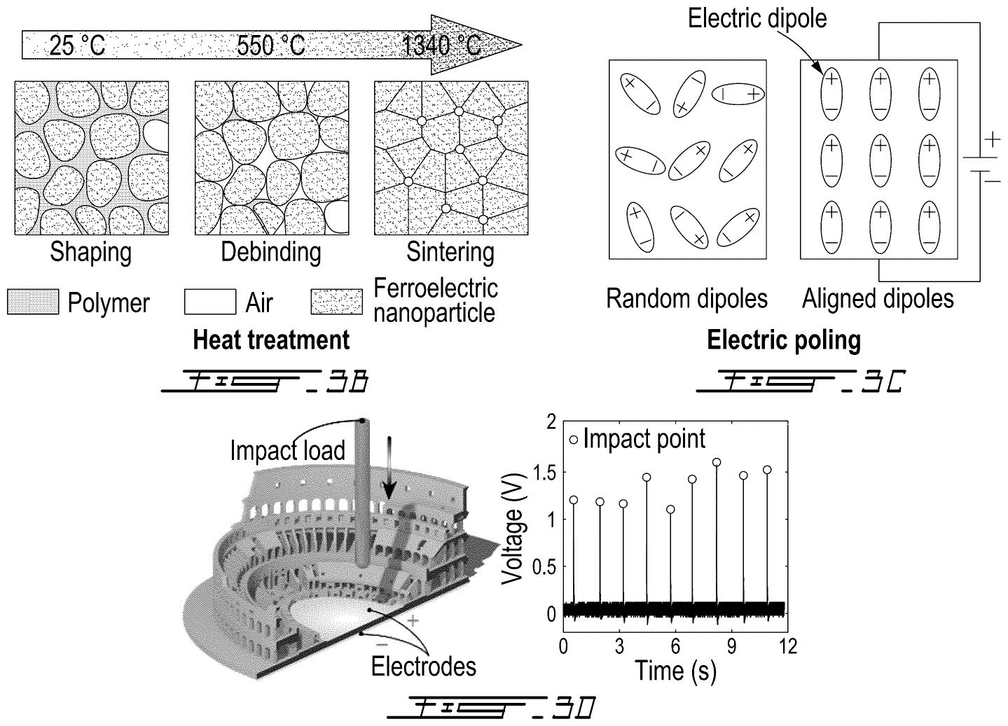

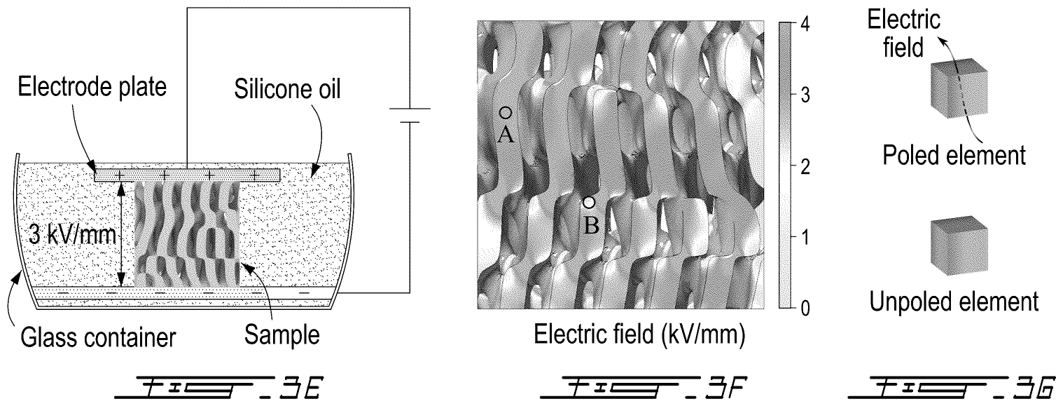

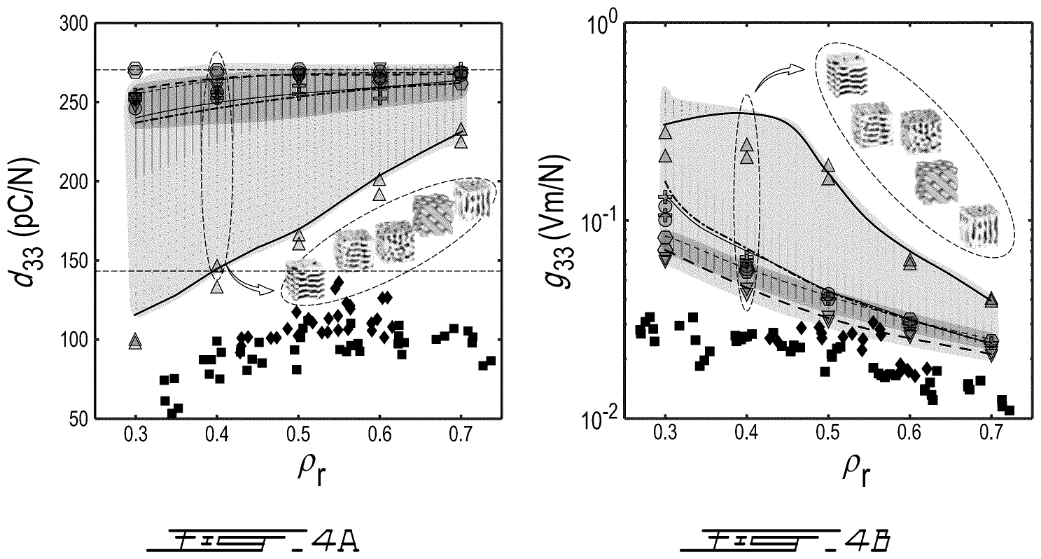

Featuring high print speed and dimensional resolution, a liquid resin-based digital light processing (DLP) 3D printing is used to allow the freeform fabrication of our rationally-designed architected ferroelectric ceramics (FIG. 3A). The lead-free barium titanate (BaTiO₃) powders with an average size of 3 μm are selected as ferroelectric ceramic fillers. The Polyethylene glycol (250) diacrylate (PEGDA 250) is used as the photosensitive resin, and diphenyl (2, 4, 6-trimethylbenzoyl) phosphine oxide (TPO) with an absorption peak range from 350 nm to 410 nm is used as photoinitiator. All these chemicals are purchased from Sigma-Aldrich and used as received. To achieve low shrinkage and precise geometry after sintering, a high solid loading (42 vol % or 80 wt %) slurry is prepared for printing. In specific, 40 g BaTiO₃ ceramic powder is well mixed with 10 g PEGDA 250 and 0.2 g TPO through a high-energy ultrasonic homogenizer (DH35-650, Lawson) for 1 hour. However, increasing the powder content would adversely affect the slurry flowability, thereby hindering the material self-leveling and causing the failure of recoating the next layer. In order to decrease the slurry viscosity, our BaTiO₃ powder is first surface treated through the dispersant BYK (BYK Chemie, Germany) with 1 wt % concentration. After modification, the slurry viscosity decreases to 162 mPa·s at a 50 s⁻¹ shear rate, which is much smaller than the critical value of 3000 mPa·s for DLP printing. The printing process is implemented by a B9 Core 530 printer with a layer thickness of 30 μm and exposure energy of 14 mJ.

In an embodiment, to obtain dense ferroelectric ceramics, a two-step heat treatment including vacuum debinding and high-temperature sintering is employed (FIG. 3B). Vacuum debinding can involve the removal of polymer from the composite green bodies in a vacuum tube furnace, in this case using model 01200-50, Zhengzhou Zylab Instruments Co., Ltd., China, at 550° C. where the violent oxidation reaction of organic substances are avoided, thereby suppressing ceramic defects. The debinded samples are then sintered, in this example at 1350° C. for 4 hours in a regular muffle furnace (M1500-12IT, Zhengzhou Zylab Instruments Co., Ltd., China) in an air atmosphere. This process is associated with considerable shrinkage and consolidation of the powder structure; at the same time, the porosity of the material is significantly reduced. The debinding process is designed according to the thermogravimetric analysis (TGA) result.

Electric polarization can then be used to activate the ferroelectric properties of sintered ceramics. As shown in FIG. 3C, all these electric dipoles within the ceramic before polarization are oriented in random directions, and its overall effect leads to an initial lack of ferroelectricity. After high voltage polarization, these randomly oriented dipoles are aligned along the electric field, and the macroscopic ferroelectric properties are preserved even without the application of an electric field. Therefore, before performing homogenization analysis, the poling simulation should be first conducted to determine the polarization direction of local elements. Our printed BaTiO₃ ceramics are polarized in an oil bath with a 3 kV/mm electric field for 30 minutes at room temperature without electric breakdown, which is strong enough to fully activate their ferroelectric properties in this embodiment.

FIG. 3E shows a schematic of the polarization setup. The as-fabricated ferroelectric ceramic is poled in a silicone oil bath using an electric field of 3 kV/mm at room temperature. Both surfaces of the sample are connected with electrode plates wired to a high voltage supply. Based on our experimental tests, an electric field (coercive field, E_{c}) of 1.5 kV/mm is sufficient to fully polarize the 3D printed BaTiO₃ ceramics. Unpolarized BaTiO₃ exhibits no ferroelectric properties. The relative permittivity of silicone oil is 5. FIG. 3F shows the magnitude of simulated polarization electric field distribution within the spinodoids where the electric field direction and magnitude are then used to numerically determine the polarization direction and ferroelectric properties of local elements (FIG. 3G).

FIG. 3D shows an elaborately printed colosseum with an overall size of 20×10×7 mm. Its fine microstructural features, such as vertical pillars (0.4 mm in diameter), demonstrate the high-resolution fabrication capabilities of the ceramic printing platform. In addition, we further coat silver electrode to the colosseum floor and conduct electric polarization. Under the impact of a slender rod, the complex building can detect the external load, which is detected by a meter, and more precisely converted into voltage signals and recorded by an oscilloscope in this example. We can precisely fabricate the designed ferroelectric spinodoids with relative density varying from 0.3 to 0.7. Both diamond shellular and tessellated spinodoid are printed without detects. After sintering, the green porous structure 14 shrinks from 8×8×8 mm to 6×6×6 mm, i.e., 25% length shrinkage.

As shown in FIG. 4A, the d₃₃ of our printed solid BaTiO₃ is 270 pC/N (black dashed line), which is almost twice that of 144.5 pC/N (red dash line) for commercial products, demonstrating 3D printing as a promising approach for the freeform fabrication of high-performance ferroelectric materials.

A wide range of d₃₃ values can be achieved, varying between 99 pC/N and 270 pC/N based on the experiments measured by a d₃₃ meter (PDK3-2000, PolyK, USA). Specifically, columnar (30°, 30°, 0°), isotropic (45°, 45°, 45°), cubic (30°, 30°, 30°), and unrotated diamond have almost the same d₃₃ values as solid BaTiO₃, which are slightly affected by the relative density. For example, the experimental values (large circle dots) for these four topologies at ρ=0.3 are 250, 253, 250, and 270 pC/N, respectively. In contrast, for porous BaTiO₃ fabricated by the BURPS method (blue square dots), the introduction of porosity leads to a decrease in d₃₃ due to insufficient polarization caused by lower breakdown strength. For freeze-caste porous BaTiO₃ (brown diamond dots), although the maximum value of d₃₃ can approach 93% of its dense material at ρ=0.55, it drops significantly when ρ is smaller than 0.55, and this value is unstable, e.g., varying between 90 and 130 pC/N when ρ is 0.6. The large data fluctuations can be observed when control over the pore topologies during the processing is not precise, e.g., pore shapes, and pore channel alignment, which can significantly affect the piezoelectric properties.

An advantage of high d₃₃ value raises from the structural features of spinodoid and diamond topologies, most of which can be fully polarized along direction x₃ at a small electric field of 1.5 kV/mm without electric breakdown, and experience negligible transverse internal stress under longitudinal load, indicating high efficiency of load transfer along direction x₃. The high resolution and good repeatability of our 3D printing also ensure consistent ferroelectric properties among replicates.

On the other hand, for lamellar spinodoid (0°, 0°, 30°), d₃₃ declines remarkably with decreasing relative density, from 230 pC/N at ρ=0.7 to 99 pC/N at ρ=0.3 in experiments.

The d₃₃ of the lamellar spinodoid (0°, 0°, 30°, 0.5) is fully activated with a stable value around 164 pC/N when the polarization electric field is greater than 2 kV/mm. In this research, the polarization electric field (3 kV/mm) is higher than its coercive. It is noted that even above 2 kV/mm, only part of the structure is polarized. For example, merely 1.7% and 11.6% volume ratios of the lamellar spinodoid are fully polarized under an overall electric field of 1.5 kV/mm and 3 kV/mm, respectively. Further increase in polarization parameters, i.e., larger electric field, longer time, and higher temperature, does not lead to improvements in d₃₃ in this example.

Structural features and polarization direction may cause the small value of its d₃₃. The d₃₃ of transversely isotropic lamellar spinodoid (0°, 0°, 30°, 0.5) is insensitive to the rotation angle α; increasing the rotation angle β results in lamellae alignment closer to the axis x₃. In specific, when α=0°, and 6=90°, the lamellar spinodoid transforms from a transverse (0°, 0°, 30°, 0.5) to a longitudinal (0°, 30°, 0°, 0.5) shape, and its d₃₃ increases from 164 to 257 pC/N. The layered structural features of the lamellar spinodoid (0°, 0°, 30°) cause the stress to be mainly concentrated in the connection region between neighboring lamellae. Therefore, only part of the lamellar spinodoid (0°, 0°, 30°, 0.5), stressed under longitudinal load, contributes to the d₃₃, and full polarization of the whole structure does not imply an increase in d₃₃. Since the polarization direction (black dash arrow) of the connection region is inclined to the axis x₃, the generated electric charges are distributed in three directions, giving rise to a small d₃₃ of the transverse lamellar spinodoid.

The metric of effective volume ratio, which evaluates the ratio of component experiencing both normalized stress exceeding 0.9 and a polarization direction aligned within 20° of axis x₃, to component only withstanding normalized stress above 0.9, can be used to explain the influence of rotation angle β, and relative density ρ on d₃₃ of lamellar spinodoid (0°, 0°, 30°). Increasing β and ρ means the polarization direction is closer to axis x₃, indicating a higher effective volume ratio (red line), and more charges distributed in direction x₃ and thus larger d₃₃ (blue line). This trend is also proved through experiments, increasing from 164 pC/N at β=0° to 257 pC/N at β=90°, and from 99 pC/N at ρ=0.3 to 240 pC/N at ρ=0.7.

Similar to porous BaTiO₃ fabricated by BURPS and freeze casting, introducing porosity leads to a decrease in relative dielectric constant k₃₃/k₀ for all spinodoid and diamond topologies. This is because polarization has a marginal influence on the dielectric properties of ferroelectrics, and less high-dielectric solid material produces less charge for a given applied voltage. In specific, apart from the transverse lamellar spinodoid, the other four structures show a near linear relationship with relative density, while the lamellar spinodoid (0°, 0°, 30°) declines significantly with decreasing relative density, from 649 at ρ=0.7 to 57 at ρ=0.3 (orange circle dots) measured by a LCR meter (SR 715, Stanford Research Systems, USA) at 1 KHz frequency. In addition, topology also has a great effect on the k₃₃/k₀. For example, when ρ=0.5, the experimental k₃₃/k₀ of columnar spinodoid is 953, while 735 for cubic spinodoid and only 105 for transverse lamellar spinodoid. It is noted that although the dielectric constant of our printed solid BaTIO₃ (k₃₃/k₀=2200) is high, the k₃₃/k₀ of transverse lamellar spinodoid may still be much less than porous BaTiO₃ prepared by BURPS (blue square dots) and freeze casting (red diamond dots) sharing the same ρ.

Piezoelectric voltage constant g₃₃ assesses the electric field generated per unit of applied mechanical stress and is obtained by d₃₃/k₃₃, with a high value implying better sensitivity to an external force. As shown in FIG. 4B, benefiting from the decrease in dielectric constant, ferroelectric spinodoid metamaterials exhibit an increasing trend with decreasing relative density. Despite lamellar spinodoid (0°, 0°, 30°) features the smallest d₃₃, its ultralow dielectric constant contributes to the highest g₃₃. For example, when ρ=0.5, the g₃₃ of columnar, isotropic, cubic, diamond, and lamellar spinodoid, are 0.032, 0.040, 0.041, 0.041, and 0.178 Vm/N, respectively. It should be mentioned that even for columnar spinodoid with a relative density of 0.7, its g₃₃ (0.021 Vm/N) is still higher than that of the solid counterpart (e.g. 0.014 Vm/N vs. 0.010 Vm/N), demonstrating the potential of spinodoid ferroelectrics in high-performance lightweight force sensors, accelerometer, and sonar devices.

To have a better understanding on the dielectric properties of lamellar spinodoid, the orientation dependence of the relative dielectric constant of transverse lamellar with ρ=0.5. Similar to d₃₃, the k₃₃/k₀ is insensitive to rotation angle α, but increases with increasing β, growing from 105 for β=0°, to 979 for β=90°. The small k₃₃/k₀ of transverse lamellar may be due to under an external voltage along direction x₃, the overhanging parts, due to the lack of a voltage path along direction x₃, share a negligible electric field; only the connection regions between adjacent lamellae generate an obvious electric field, which contributes to the overall dielectric constants.

We define the effective volume ratio as the ratio of components producing a normalized electric field exceeding 0.6 to the entire structure to evaluate the effect of rotation angle β and relative density on the k₃₃/k₀. Increasing β results in more material aligned along the direction x₃, indicating a higher effective volume ratio and k₃₃/k₀; similarly, increasing relative density means more materials distributed in the connection region, leading to a higher relative dielectric constant. This relationship is proved both theoretically (solid lines) and experimentally (orange dots).

To test the voltage response of our spinodoid metamaterials to mechanical force, an impact load is applied to the printed samples, whose reaction force is measured by a load cell (Model 1216, ADMET), and the generated voltage is recorded by an oscilloscope (SDS 1103X-E, SIGLENT). The generated voltage was measured for seven structures, i.e., columnar, diamond, isotropic, and cubic with ρ of 0.5, and lamellar with ρ of 0.5, 0.6, and 0.7. For better comparison, the voltages given here are normalized by the applied force per newton. As predicted by the FEM simulation, the lamellar spinodoid with a relative density of 0.5 shows the highest average output voltage (˜92 V), which is around 3 times that of the columnar one (˜31 V).

As shown in FIG. 5A, both spinodoid and diamond metamaterials provide diverse sources of transverse piezoelectric anisotropy between d₃₁ and d₃₂. Although these two values of solid ferroelectric ceramics (such as BaTiO₃, PZT, PMN-PT) share the same negative value, i.e., located in phase III (−, −), by tailoring the spinodoid and diamond topologies, unprecedented combinations of d₃₁ and d₃₂, located in phase I (+, +), phase II (−, +), and phase IV (+, −), are obtained both theoretically and experimentally. For example, the (d₃₁, d₃₂) value of (15, 19) pC/N in phase I (+, +) are measured from the isotropic spinodoid (45°, 45°, 45°, 0.30); the (d₃₁, d₃₂) value of (−54, 37) pC/N in phase II (−, +) are measured from the lamellar spinodoid (0°, 30°, 0°, 0.40), and the (d₃₁, d₃₂) value of (31, −60) pC/N in phase IV (+, −) is measured from the lamellar spinodoid (30°, 0°, 0°, 0.40). In contrast, without rational design, the (d₃₁, d₃₂) of porous ferroelectric ceramics is located in phase III (−, −), and decreases rapidly in magnitude with decreasing relative density. However, for columnar spinodoid (30°, 30°, 0°) in phase III (−, −), its (d₃₁, d₃₂) still can maintain high value of (−100, −103) pC/N even when ρ=0.7, approaching 95% of that of the solid BaTiO₃ (black dash line at −110 pC/N).

Different from the strategy of manipulating the electric displacement map by adjusting truss angles of piezoelectric lattice metamaterials, the desired transverse piezoelectric anisotropy of spinodoid and diamond metamaterials is obtained by tuning the relative density and structural topology. Generally, decreasing relative density leads to increased d₃₁ and d₃₂. At high relative densities, d₃₁ and d₃₂ are negative for all these topologies. For example, when ρ=0.7, the experimental (d₃₁, d₃₂) values for columnar (30°, 0°, 0°), isotropic (30°, 0°, 0°), unrotated diamond, and longitudinal lamellar (0°, 30°, 0°) are (−100, −103), (−60, −64), (−50, −51), and (−103, −55) pC/N, respectively. Furthermore, the responses of d₃₁ and d₃₂ to varying ρ are highly topology-dependent. Particularly, for columnar spinodoid (30°, 0°, 0°), both d₃₁ and d₃₂ increase almost simultaneously from −103 to −4 pC/N when ρ varies from 0.7 to 0.3. On the contrary, for longitudinal lamellar (0°, 30°, 0°), the d₃₁ is stable at around −100 pC/N when ρ>0.6, and then increases with decreasing relative density; while its d₃₂ increases continuously with declining ρ.

FIG. 5B shows the voltage responses of three spinodoids with representative transverse piezoelectric anisotropies under uniaxial impacts along three directions. In specific, the (d₃₁, d₃₂) values for columnar (30°, 30°, 0°, 0.6), lamellar (0°, 30°, 0°, 0.55), and lamellar (0°, 30°, 0°, 0.45) are (−83, −78), (−98, −4), and (−71, 26) pC/N, respectively. Due to its negative d₃₁ and d₃₂, and positive d₃₃, the columnar spinodoid generates voltages of around −8V under both direction x₁ and direction x₂ impacts, while positive voltages of around 20V under direction x₃ impacts. Since the d₃₂ value of lamellar (0, 30°, 0, 0.55) is around 0, its responses to direction x₂ impacts are almost negligible. As for lamellar (0, 30°, 0, 0.45), the positive d₃₂ causes it to generate positive voltages under both direction×2 (around 8V) and direction x₃ (around 30V) impacts. Different signs of the normalized voltage produced under direction x₁ (around 1) and direction×2 (around −0.5) compression of lamellar (0, 30°, 0, 0.45) are also simulated and demonstrated.

To explain the transverse piezoelectric anisotropy of (0°, 30°, 0°, 0.45), the influence of relative density on effective d₃₁ and d₃₂, can be obtained by the following equations:

$${d}_{31} = \frac{1}{V} {\sum }_{i = 1}^{{N}_{ele}} {V}_{i} ( {d}_{31 , s} {σ}_{1 , i} + {d}_{32 , s} {σ}_{2 , i} + {d}_{33 , s} {σ}_{3 , i} ) \qquad ( 3 )$$

$$and$$

$${d}_{32} = \frac{1}{V} {\sum }_{i = 1}^{{N}_{ele}} {V}_{i} ( {d}_{31 , s} {σ}_{1 , i} + {d}_{32 , s} {σ}_{2 , i} + {d}_{33 , s} {σ}_{3 , i} ) \qquad ( 4 )$$

where Nₑₗₑ is the number of element; V is the overall size of spinodoid; Vᵢ, and σ_{k,i} (k=1, 2, 3) are the volume and stress of i^{th} element; d_{31,s}, d_{32,s}, and d_{33,s} are piezoelectric constants of the solid BaTiO₃. The histograms below present the volume ratio of elements experiencing a normalized stress component σ₃ exceeding 0.9 to the entire structure. When ρ>0.5, the d₃₁ is close to that of the solid BaTiO₃. This is because at high relative density, the lamellae is mainly aligned along direction x₁ and direction x₃. Thus, most of the structure is stressed along direction x₁ under direction x₁ load, resulting in stable d₃₁ values around −100 pC/N. As ρ decreases, the inclined connection region accounts for more volume fraction over the whole structure, which decomposes the direction x₁ load into more internal stress along three directions, i.e., increased volume ratio, and leads to a decrease in the d₃₁ magnitude. This behavior is more obvious for d₃₂, whose magnitude decreases even at high relative density. For load along direction x₂, decreasing relative density results in increased stress components σ₃, e.g., volume ratio varying from 0.30 at ρ=0.7 to 0.88 at ρ=0.3. It is noted that since d₃₂ and d₃₃ of solid BaTiO₃ share different signs, the lamellar (0°, 30°, 0°) finally approaches a positive value of effective d₃₂. This metric can also be used to explain other types of topologies. In addition, hydrostatic piezoelectric constant, dₕ=d₃₁+d₃₂+d₃₃, which evaluates the hydrophone device performance, will also benefit from the increased transverse piezoelectric constant at low relative density.

Our spinodoid metamaterials also enable the functionally graded (FG) design, where multiple different topologies can be smoothly combined. As shown in FIG. 5C, the FG spinodoid consists of lamellar (0°, 30°, 0, 0.45) and isotropic (45°, 45°, 45°, 0.55) topologies, which is also 3D printed in high quality with a size of 5×14.5×5 mm. No electrode covers the transition region and four electrodes are attached in the top and bottom surfaces of these two topologies, where V₁ measures the voltage difference for lamellar part and V₂ indicates the voltage difference for isotropic region.

Based on CNN prediction, the d₃₁ values for the above lamellar and isotropic topology are 32 and −21 pC/N, respectively. Thus, under direction x₁ compression, the longitudinal lamellar generates a positive voltage, while the isotropic spinodoid produces negative voltage. Interestingly, the signs of these two voltages, i.e., V₁ and V₂, are not changed even when coupled in the FG design, represented by the orange (positive) and blue (negative) colors in the left simulation. Since the d₃₃ of both topologies is positive, the voltage responses of both spinodoids to the direction 3 compression are positive, indicated by the orange color of the entire top surface in the right simulation. These behaviors are also verified by experimental impact test, where the average V₁ for direction x₁ and direction x₃ impacts are 4V and 17V, respectively; while −2V and 10V for V₂, respectively.

Based on the FG design, we can program the voltage response of local electrodes, one of which application is to detect the load direction. For example, if V₁ and V₂ have the same sign, the load is in the x1-direction, and vice versa, along x3-direction. However, the load directions along x2 and x3 are indistinguishable, with both V₁ and V₂ being either positive or negative. To identify the three load directions, a new FG spinodoid consisting of four spinodoids, i.e., lamellar (45°, 45°, 45°, 0.55), lamellar (30°, 0°, 0°, 0.45), isotropic (45°, 45°, 45°, 0.55), and isotropic (0°, 30°, 0°, 0.45), is designed and printed with a size of 11.4×11.4× 3.8 mm. In addition, four pairs of electrodes are attached to the top and bottom surfaces of local intact spinodoids, and labeled as V1, V2, V3, and V4, respectively. Unlike the strategy of stacking multiple unit cells, a one-step three-dimensional force sensor can be based on a single ferroelectric material and produced via a single polarization step. As predicted by FEM simulations, V3 has a different sign from V1, V3, and V4 under x1-direction impact; under x2-direction impact, V1 is positive while V2, V3, and V4 are negative; since d33 of all spinodoids are positive, V1, V2, V3, and V4 share the same positive sign. Therefore, we can judge the three load directions by analyzing the signs of these four voltages.

Our multifunctional spinodoid metamaterials can also be employed as building blocks for structural health monitoring. Four isotropic spinodoids (45°, 45°, 45°, 0.55) are located in the middle of the Eiffel tower. Compared to bulk material, our spinodoids comply with the lightweight design of the Eiffel Tower without sacrificing their piezoelectric properties. Under x1-direction impact, spinodoids A and B are in compression, while spinodoids C and D are in tension, which leads to negative values of VA and VB, and positive values of VC and VD. Similarly, under x2-direction impact, VA and VC are positive (˜1.5V), and VB and VD are negative (˜−1.5V). For diagonal force at 45° to the x1 direction, spinodoid B is in compression and spinodoid C is in tension, while spinodoids A and D experience negligible forces. As a result, VB and VC share different signs and large magnitudes (1.5V and −1.5V, respectively), while VB and VC are almost zero. Therefore, by comparing the voltage outputs of these four spinodoids, we can detect the structure load directions.

Structural defect testing is conducted by applying axial impacts along the top of the tower. If the entire structure has no defect, the four voltage outputs should be similar (left test). However, when the truss on one side of the building is cracked or removed, its stiffness becomes weaker and the spinodoid block on that side generates less voltage (VC in middle test). In addition, for shape defects (13° bending towards x2-direction), due to the inclined angle between axial impact and x3 direction, spinodoids B and D are in compression while A and C are in small tension (right test), leading to VB and VD around −3V and VA and VC around −2V. FEM simulations of a simplified model provide an intuitive explanation on our experiments, with normalized voltage outputs are shown in bar chats. In addition, if more spinodoid ferroelectric blocks are built in the structure, more information, such as load position and bending angle, can be obtained. Furthermore, under the excitation of ambient vibrations, such as wind and human motion, ferroelectric blocks can harvest mechanical energy for developing the next-generation of smart infrastructures.

The polarized ferroelectric materials not only demonstrate the piezoelectric effect (electromechanical coupling) but also the pyroelectric effect (thermoelectric coupling). The increase in temperature enhances the thermal vibration of electric dipoles, leading to their oscillation to a larger degree, β, around their respective polarization axis. This oscillation significantly reduces the magnitude of polarization, resulting in a reduction of the number of free charges attached to the material surfaces, and thus generating voltage in an open circuit. Conversely, when ferroelectric materials are cooled down, the region of dipole vibration, γ, becomes smaller (β>γ), leading to an increase in the spontaneous polarization and the generation of a reversed voltage. The simulated normalized voltage distributions of the isotropic spinodoid metamaterial under heating and cooling process. In this case, the bottom surfaces are grounded electrically, while the electric potential of the top surface shifts from positive to negative as the temperature decreases. The voltage response of 3D printed isotropic spinodoid ferroelectrics (size of 8×8×2 mm) under heating and cooling process was acquired. A temperature increase of 20° C. (from the room temperature 298 K to 318K) is achieved using a hot plate and lasts for 4 minutes. The sample is then separated from the thermal source and allowed to cool through natural convection with air for another 4 minutes. This process is repeated for six times. After three cycles, the maximum voltage generated during the heating phase remains stable around 53 V, whereas during the cooling phase, it reaches a minimum of −36 V. The switching of the voltage signal provides evidence that the generated voltage is attributed to the pyroelectric effect, rather than the piezoelectric effect caused by mechanical forces.

The pyroelectric constant, p₃, describing the variation in electric charge per unit of surface area in response to a given temperature change, is examined. This parameter is also experimental measured by PolyK pyroelectric test system. In general, reducing the relative density results in a decrease in p₃, primarily because fewer materials contribute to charge generation. Moreover, the inclined structural characteristics of lamellar spinodoids cause a further decrease in p₃ due to the increased division of charge components along directions 1 and 2. This observation is also supported by experimental measurements. For instance, the pyroelectric coefficient (p₃) of columnar spinodoid decreases from 151 μC/m²/K to 102 μC/m²/K as the relative density changes from 0.7 to 0.5. In comparison, solid BaTiO₃ exhibits a p₃ value of 270 μC/m²/K. Furthermore, the lamellar spinodoid demonstrates a significantly lower p₃ value of only 21 μC/m²/K when the relative density is 0.5. Contrarily, the figure of merit p₃/k₃, which evaluates the voltage sensitivity at a given temperature variation, shows distinct trends compared to p₃ due to the decreased dielectric constant (k₃) at decreased relative densit. Except for lamellar spinodoid, all other types of spinodoid and diamond with varying ρᵣ exhibit nearly constant values comparable to those of solid materials i.e., 13.9×10³ V/m/K. Interestingly, reducing the relative density efficiently enhances the p₃/k₃ of lamellar spinodoid. For example, the p₃/k₃ values of columnar, cubic, isotropic, and diamond ferroelectrics are 12.2×10³ V/m/K, 11.6×10³ V/m/K, 12.1×10³ V/m/K, and 12.6×10³ V/m/K, respectively with ρᵣ as 0.5; in contrast, the lamellar spinodoid exhibits a significant increase in the p₃/k₃ value, rising from 13.8×10³ V/m/K (ρᵣ=0.7) to 22.8×10³ V/m/K (ρᵣ=0.5). Another important figure of merit, F_{V}, is employed to assess the voltage sensitivity of pyroelectric devices, It evaluates the voltage response of ferroelectric materials for a given thermal power input, and given by F_{V}=p₃/(c_{E}·k₃), where c_{E} is the volume specific heat capacity. Since introducing porosity decreases volume specific heat capacity, F_{V} values of all ferroelectric topologies and diamond show an increasing trend with decreasing ρᵣ. For examples, the F_{V} of isotropic spinodoid is 7.2×10⁻³ m²/K when ρᵣ=0.7 and increases to 10.2×10⁻³ m²/K when ρᵣ=0.5, indicating the potential of spinodoid ferroelectric in high performance pyroelectric thermal sensor.

Similar to the structural health monitoring functionality depicted in FIG. 5C, the smart Eiffel tower can also utilize the pyroelectric effect for fire direction and motion detection in its vicinity. For example, in the event of a fire breaking out on the right side of the tower, spinodoids B and D generate a higher voltage (˜3.5V) within the initial 20 seconds due to their greater thermal absorption, whereas spinodoids A and C demonstrate a lower voltage (˜1.1V). Conversely, when the candle is located at the bottom side, V_{A} and V_{B} (˜4.0V) are significantly higher than V_{C} and V_{D} (˜1.1V). Since the amount of thermal absorption, or distance between the candle and the tower, determines the voltage increasing rate of ferroelectric material, we can detect fire movement by analyzing the voltage response. The candle undergoes a cyclic forward and backward movement controlled by a linear actuator, resulting in a displacement of 1 cm achieved in 5 seconds. By analyzing the instantaneous voltage increasing rate, i.e., dU/dt in, we can accurately predict the movement condition of the fire source. Specifically, an increasing dU/dt indicates forward movement, while a decreasing dU/dt suggests backward movement.

After fabrication, the dipole moments within the ferroelectric ceramic are initially randomly oriented and cannot produce the overall piezoelectric/pyroelectric effect. A polarization process, in which a high electric field is applied to the ferroelectric materials, is required to align these dipole moments in the same direction. Therefore, before performing the homogenization analysis to obtain the effective properties of the ferroelectric spinodoid metamaterials, the polarization process is first simulated to determine the local polarization direction of the unit cell.

In summary, based on the modified numerical homogenization, the effective piezoelectric properties of six thousand cases of randomly generated spinodoid metamaterials are obtained. The generated data are then used to train a widely used machine learning method, i.e., CNN, which makes it possible to investigate the influence of geometry parameters on the effective piezoelectric properties of spinodoid through analysis on massive cases of different structures. 3D printing technology is developed and ferroelectric ceramics are fabricated into the shape of our delicately selected spinodoid topologies. By tailoring the spinodoid topologies, we can realize unconventional multiphysical properties unachievable from conventional fabricated porous piezoelectric materials. For example, the d33 value of columnar spinodoids maintain a constant value as that of solid material even with decreased relative density. The effective dielectric constant not only depends on the relative density, but also on the structure architectures. For example, the dielectric constant of lamellar spinodoid can be as small as 4.8% of that of solid counterpart with relative density of 0.5. This low dielectric constant contributes to improved piezoelectric figures of merit, i.e., g33. In addition, desired transverse piezoelectric anisotropy can also be achieved by tailoring the spinodoid topologies. This work highlights the potential of spinodoid piezoelectric metamaterial as the next generation of sensor and building blocks for smart architectures.

Indeed, in the context of a smart building, or a smart structures, the porous structure 14 having the spinodoid geometry made of a polarized ferroelectric material may be used as a building block in a structure, such as a brick and mortar bridge for instance. Such an approach may be useful in many embodiments, such as for fire detection, motion detection, structure health monitoring, etc.

The results presented above demonstrate that the porous structure 14 having a spinodoid geometry and made of a polarized ferroelectric material may be useful as a sensor, such as in an embodiment where the device electrically connected to it includes a voltmeter. One feature which indicate suitability as a sensor is the possibility of achieving a d33 which is significantly higher than the k33. Indeed, a structure which exhibits both a high d33 and a low k33 can be expected to perform well as a sensor or as an energy harvester, in accordance with knowledge of persons having ordinary skill in the art. Moreover, a structure which exhibits a high d33 can be expected to perform well as an actuator, in accordance with knowledge of persons having ordinary skill in the art. In the context of a thermoelectromechanical system 10 which is embodied as an actuator, or as a energy harvester, the device 12 connected to the porous structure 14 can be adapted accordingly. For instance, the device 12 can be an electrical source in the case of an actuator, where the device 12 is operable to cause a difference of potential between two electrodes in contact with separate areas of the porous structure. In the case where the thermoelectromechanical system 10 is embodied as an energy harvester, the device 12 can include a battery and/or a voltage regulator, for instance. Accordingly, it can be expected from the results reported above that a porous structure 14 having a spinodoid geometry and made of a polarized ferroelectric material may be useful as an actuator and/or as an energy harvester in addition to having potential for use as a sensor.

As can be understood, the examples described above and illustrated are intended to be exemplary only. The scope is indicated by the appended claims.

What is claimed is:

1. A thermoelectromechanical system comprising:
a porous structure having a spinodoid geometry and formed of an electrically polarized ferroelectric material, the structure occupying a volume and having a first area spaced apart from a second area; and
a device electrically connected to the first area and to the second area.

2. The thermoelectomechanical system of claim 1 wherein the device is a voltmeter.

3. The thermoelectromechanical system of claim 1 wherein the device is a generator.

4. The thermoelectromechanical system of claim 1 wherein the device has an electrical power source.

5. The thermoelectromechanical system of claim 1 wherein the geometry satisfies equation
$$φ ( x ) = \sqrt{\frac{2}{N}} {\sum }_{i = 1}^{N} cos ( β {n}_{i} \cdot x + {γ}_{i} ) , {γ}_{i} ∼ [ 0 , 2 π ] ,$$
where N is a number of standing sinusoidal waves greater than 20, β is a constant wavenumber of the standing sinusoidal waves which is greater than 0 denoting an early stage of spinodal decomposition, where x is a position vector, nᵢ is a unit wave vector randomly selected from a spherical design space, and γᵢ is a random phase angle sampled from a uniform distribution within the design space.

6. The thermoelectromechanical system of claim 5 where binary indicator function determines
$$G ( x ) = \{ \begin{matrix}1 & if φ ( x ) \leq {φ}_{0} & ( Solid material ) \\ 0 & if φ ( x ) \leq {φ}_{0} & ( Void / air )\end{matrix}$$
whether material or void is present at position x, where φ₀ is a level cut value calculated by exploiting the Gaussian properties of the random field as φ₀=\sqrt{2} inverf (2ρ−1), where inverf ( . . . ) is the inverse error function, and ρ is relative density.

7. The thermoelectromechanical system of claim 6 wherein ρ∈[0.3, 0.7].

8. The thermoelectromechanical system of claim 7 wherein angles, θ₁, θ₂, and θ₃<π/2, are used to determine the design space and are related to axis x₁, x₂ and x₃, respectively, in a Cartesian coordinate system.

9. The thermoelectromechanical system of claim 5 where the wave vector, nᵢ, is restricted to specific spherical regions, favoring some directions and neglecting the others.

10. The thermoelectromechanical system of claim 1 wherein the spinodoid geometry is lamellar.

11. A method of making a porous structure, the method comprising:
mixing ferroelectric powder and resin into a mixture;
3D printing the mixture into a spinodoid geometry, thereby forming the porous structure;
debinding the porous structure;
sintering the debinded porous structure; and
electrically polarizing the sintered porous structure.

12. A porous structure having a spinodoid geometry and formed of an electrically polarized ferroelectric material.
